(19) United States
(12) Patent Application Publication
(10) Pub. No.: US 2013/0163183 A1
(43) Pub. Date: Jun. 27, 2013

(54) HARD DISK CARRIER

(71) Applicant: CHIH-HAO LIN, Tu-Cheng (TW)

(72) Inventor: CHIH-HAO LIN, Tu-Cheng (TW)

(21) Appl. No.: 13/663,672

(22) Filed: Oct. 30, 2012

(30) Foreign Application Priority Data
Dec. 26, 2011 (TW) 100148721

(51) Int. Cl. H05K 9/00; G06F 1/16

(52) U.S. Cl. 361/679.33

(57) ABSTRACT

A hard disk carrier includes a receiving frame, a plane, and an electromagnetic shielding module. The receiving frame is used to hold a hard disk. The electromagnetic shielding module is mounted between the receiving frame and the plane. The electromagnetic shielding module defines a plurality of openings through the opposite ends. The edge of each opening extending outward from the surface and forming a cylinder peripheral wall, each opening and the peripheral wall corresponding to the opening forming a waveguide.

### BACKGROUND

1. Technical Field

The present disclosure relates to a hard disk carrier, and particularly to a hard disk carrier with electromagnetic shielding.

2. Description of Related Art

When a hard disk is working, it generates electromagnetic radiation with some frequency, and then the electromagnetic radiation is transmitted to the computer chassis, causing some harmful influence to other elements of the computer. So that, it is necessary to produce a hard disk carrier to receive the hard disk, to avoid any electromagnetic radiation transmitted to the computer chassis generated by the hard disk.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial cutaway, and isometric view of an exemplary embodiment of a hard disk carrier.

FIG. 2 is an exploded, isometric view of the hard disk carrier shown in FIG. 1.

FIG. 3 is a front-on view of an electromagnetic shielding module of the hard disk carrier.

FIG. 4 is a cross-sectional view of the electromagnetic shielding module taken along line IV-IV of FIG. 3.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one”.

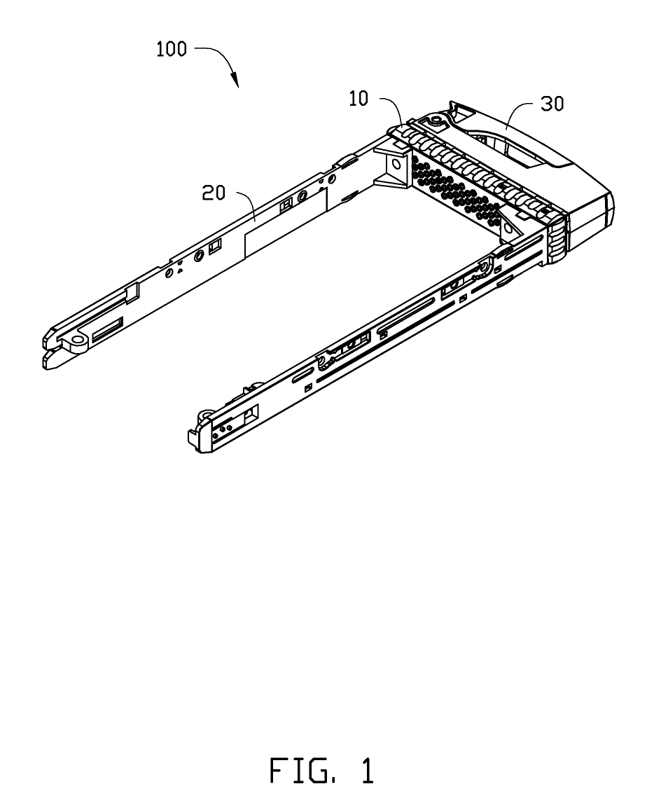

FIG. 1 is a partial view of an exemplary embodiment of a hard disk carrier 100. The hard disk carrier 100 can be mounted in a computer chassis (not shown), and hold a hard disk (not shown).

The hard disk carrier 100 includes an electromagnetic shielding module 10, a receiving frame 20, and a panel 30. The electromagnetic shielding module 10 is mounted between the receiving frame 20 and the panel 30. The receiving frame 20 is used to carry a hard disk. The electromagnetic shielding module 10 is used to shield the electromagnetic radiation generated by the hard disk.

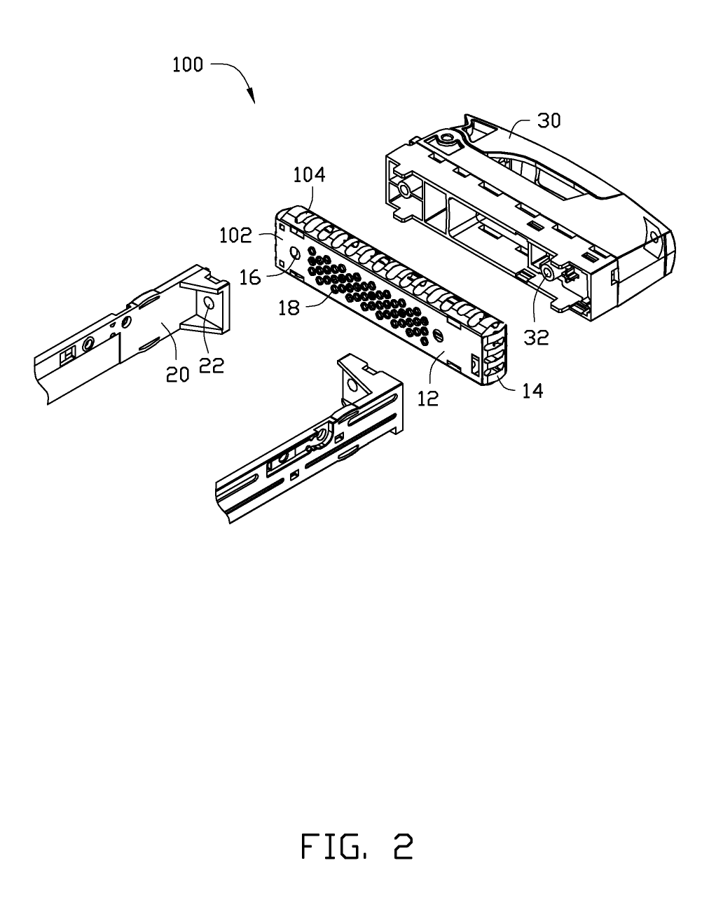

FIG. 2 is an exploded isometric view of the hard disk carrier 100 shown in FIG. 1. Referring to FIG. 1 and FIG. 2, the electromagnetic shielding module 10 is made of metallic material. The electromagnetic shielding module 10 includes a main portion 12 and an extending portion 14. The main portion 12 is a rectangular plate and includes a first surface 102 and a second surface 104. Each extending portion 14 is rectangular shaped piece. The plurality of extending portions 14 are connected to the edges of the main portion 12 and are extended from the main portion 12 in the same direction. The main portion 12 and the extending portions 14 are connected to form a hollow case. The main portion 12 and the extending portions 14 can be made by integral modeling method. The main portion 12 defines two first connecting holes 16 through the opposite ends.

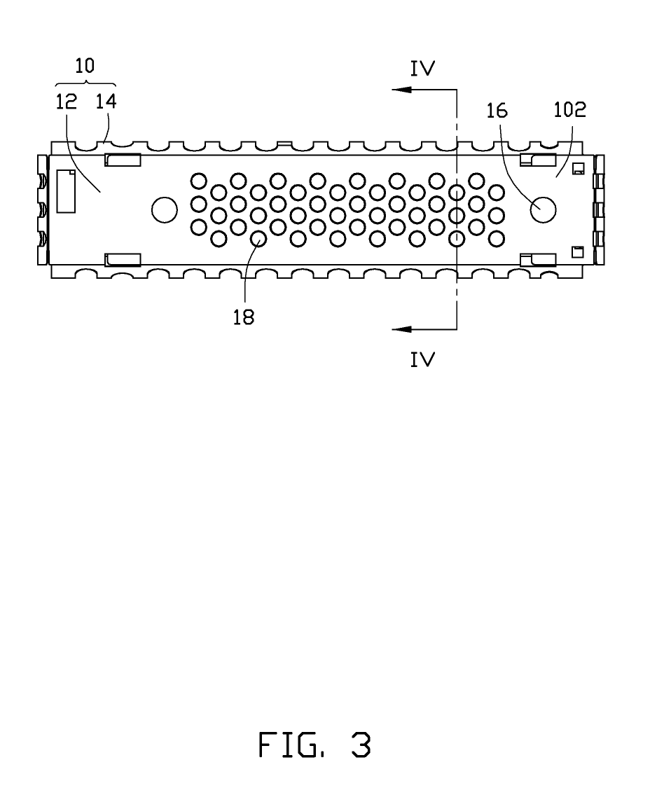

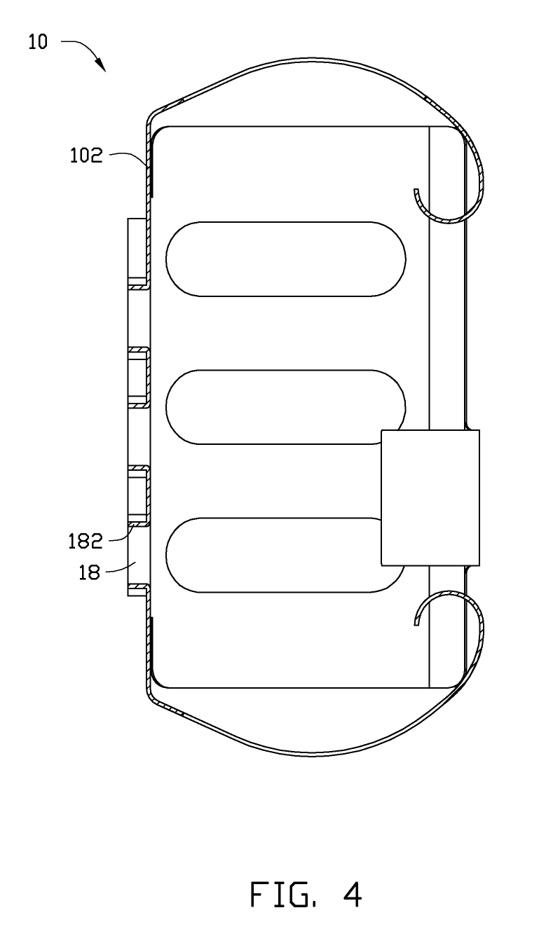

FIG. 3 is a front-on view of the electromagnetic shielding module 10 of the hard disk carrier 100. FIG. 4 is a cross-sectional view of the electromagnetic shielding module 10 taken along line IV-IV of FIG. 3. Referring to FIG. 3 and FIG. 4, the main portion 12 defines a plurality of circular openings 18 through a middle. The plurality of openings 18 are spaced from each other. An edge of each circular opening 18 is extended outward from the first surface 102 of the main portion 12 and forms a cylinder peripheral wall 182. According to the waveguide theory, each opening 18 and the peripheral wall 182 correspond to the opening 18 form a waveguide, with a cut-off frequency. When the hard disk carried by the hard disk carrier 100 generates any electromagnetic wave when at work and when frequency of these electromagnetic wave is lower than the cut-off frequency, the electromagnetic wave cannot pass through the openings 18. The plurality of openings 18 can be formed as electromagnetic shielding waveguides. The electromagnetic shielding waveguides formed by the openings 18 can electromagnetic shield the electromagnetic wave generated by the hard disk and avoid the electromagnetic wave transmit to the computer chassis and other elements of the computer, and then protect the other elements of the computer of working normally.

The length of each waveguide is equal to the thickness of the main portion 12 and the axial length of the peripheral wall 182. The cut-off frequency of the waveguide can be regulated by adjusting the thickness of the main portion 12, the axial length, and the internal diameter of the peripheral wall 182, so that the waveguides of the electromagnetic shielding module 10 are suitable for different frequency generated by different types of hard disk. Besides, the plurality of openings 18 are used to heat radiation for the hard disk also.

The receiving frame 20 is connected to the first surface 102 of the electromagnetic shielding module 10 and forms an U shape. The receiving frame 20 is used to receive the hard disk. Each of the two opposite ends of the receiving frame 20 defines a second connecting hole 22 respectively.

The panel 30 is rectangular box-shaped and connected to the second surface 104 of the electromagnetic shielding module 10. The panel 30 is attached to the extending portion 14. The surface of the panel 30 towards the electromagnetic shielding module 10 defines two third connecting holds 32 on the different ends.

In assembly, the receiving frame 20, the electromagnetic shielding module 10, and the panel 30 are connected together to form a whole piece by passing a connecting piece (not shown) through the second connecting holes 22, the first connecting holes 16, and the third connecting holes 32 orderly.

The electromagnetic shielding module 10 is mounted between the receiving frame 20 and the panel 30, so that, when the hard disk carrier 100 is carrying a hard disk, the electromagnetic shielding module 10 can shield the electromagnetic radiation generated by the hard disk. The plurality of openings 18 defined on the electromagnetic shielding module 10 can shield the electromagnetic radiation generated by the working hard disk and can be used to dissipate heat radiation from the hard disk as well. Therefore, the electromagnetic shielding module 10 is multipurpose, it is safe and convenient to use.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A hard disk carrier, comprising:
a receiving frame configured to hold a hard disk;
a panel; and
an electromagnetic shielding module mounted between the receiving frame and the plane, wherein the electromagnetic shielding module defines a plurality of openings therethrough, an edge of each opening extends outward from the surface forming a peripheral wall, each opening and the peripheral wall corresponding to the opening form a waveguide.

2. The hard disk carrier of claim 1, wherein the electromagnetic shielding module comprises a main portion and a plurality of extending portions, the main portion is a rectangular plate, the main portion defines two first connecting holes through the opposite ends thereof, and the plurality of extending portions are extended outward from the edges of the main portion in the same direction.

3. The hard disk carrier of claim 2, wherein the main portion and the extending portions of the electromagnetic shielding module are made by integral modeling.

4. The hard disk carrier of claim 2, wherein the main portion comprises a first surface and a second surface, the peripheral wall is extended outward from the first surface, the extending portions are extended outward from the second surface.

5. The hard disk carrier of claim 4, wherein the receiving frame is connected to the first surface of the electromagnetic shielding module and forms an U shape, together with the electromagnetic shielding module.

6. The hard disk carrier of claim 4, wherein the receiving frame defines two second connecting holes through the opposite ends, and the second connecting holes correspond to the first connecting holes of the electromagnetic shielding module.

7. The hard disk carrier of claim 6, wherein the panel defines two third connecting holes through different ends thereof, the third connecting holes correspond to the first connecting holes of the electromagnetic shielding module, and the panel attached to the extending portions of the electromagnetic shielding module.

8. The hard disk carrier of claim 1, wherein each of the plurality of openings is circular.

9. The hard disk carrier of claim 1, wherein the peripheral wall of each opening is cylinder.
